(19) United States
(12) Patent Application Publication
(10) Pub. No.: US 2020/0199752 A1
(43) Pub. Date: Jun. 25, 2020

(54) BAFFLE, SHOWERHEAD ASSEMBLY, APPARATUS FOR PROCESSING A SUBSTRATE INCLUDING THE SAME, AND METHOD OF PROCESSING A SUBSTRATE USING THE APPARATUS

(71) Applicant: SAMSUNG ELECTRONICS CO., LTD., SUWON-SI (KR)

(72) Inventors: MIN-JOON KIM, GWANGMYEONG-SI (KR); MYOUNG-WOON KIM, SUWON-SI (KR); HEE-JONG JEONG, HWASEONG-SI (KR); IL-WOO KIM, HWASEONG-SI (KR); JAE-HOON PARK, YONGIN-SI (KR); JI-WOON IM, HWASEONG-SI (KR); HYUN-GON PYO, SEOUL (KR)

(21) Appl. No.: 16/511,377

(22) Filed: Jul. 15, 2019

(30) Foreign Application Priority Data
Dec. 20, 2018 (KR) 10-2018-0165778

(51) Int. Cl. C23C 16/455; C23C 16/458

(52) U.S. Cl. CPC C23C 16/45591; C23C 16/4583; C23C 16/45565

(57) ABSTRACT

A baffle including a base plate disposed in a central portion of a showerhead in an apparatus for processing a substrate. An extension plate is movably connected to a planar surface of the base plate. The extension plate is configured to extend and contract radially from the base plate to change a diameter of the baffle.

### CROSS-RELATED APPLICATION

This application claims priority under 35 USC § 119 to Korean Patent Application No. 10-2018-0165778, filed on Dec. 20, 2018 in the Korean Intellectual Property Office (KIPO), the contents of which are herein incorporated by reference in their entirety.

### TECHNICAL FIELD

The present disclosure relates to a substrate processing and, more specifically, to a baffle, a showerhead assembly, an apparatus for processing a substrate including the same, and a method of processing a substrate using the apparatus.

### DISCUSSION OF THE RELATED ART

Generally, a deposition apparatus may include a chuck disposed on a bottom surface of a deposition chamber to support a substrate, a showerhead disposed in an upper region of the deposition chamber to provide the substrate with a reaction gas, etc. A baffle for providing the showerhead with the reaction gas may be disposed on the showerhead.

According to related arts, the baffle might not uniformly provide the showerhead with the reaction gas. Thus, an amount of the reaction gas supplied to a central portion of the substrate may be greater than an amount of the reaction gas supplied to an edge portion of the substrate. As a result, a layer on the central portion of the substrate may be thicker than that of the layer on the edge portion of the substrate.

### SUMMARY

A baffle including a base plate disposed in a central portion of a showerhead in an apparatus for processing a substrate. An extension plate is movably connected to a planar surface of the base plate. The extension plate is configured to extend and contract radially from the base plate to change a diameter of the baffle.

A showerhead assembly includes a showerhead including a plurality of injection holes. A baffle including a base plate, the baffle being disposed in a central portion of the showerhead, the baffle further including an extension plate movably connected to a planar surface of the base plate so as to extend in radial directions to change a diameter of the baffle.

A showerhead assembly includes a showerhead having a plurality of injection holes. A baffle is disposed in a central portion of the showerhead. The baffle has a diameter of about 0.05 times to about 0.15 times a length between outermost injection holes of the plurality of injection holes on a diameter line of the showerhead.

An apparatus for processing a substrate includes a processing chamber. A chuck is disposed on a bottom surface of the processing chamber and supports the substrate. A showerhead is disposed in an upper region of the processing chamber. The showerhead includes a plurality of injection holes configured to inject a reaction gas to the substrate. A baffle includes a base plate. The baffle is disposed in a central portion of the showerhead. The baffle further includes an extension plate movably connected to a planar surface of the base plate in radial directions of the base plate to change a diameter of the baffle.

An apparatus for processing a substrate includes a processing chamber. A chuck is disposed on a bottom surface of the processing chamber and is configured to support the substrate. A showerhead is disposed in an upper region of the processing chamber. The showerhead includes a plurality of injection holes each of which is configured for injecting a reaction gas to the substrate. A baffle is disposed in a central portion of the showerhead. The baffle has a diameter of about 0.05 times to about 0.15 times a length between outermost injection holes of the plurality of injection holes on a diameter line of the showerhead.

A method of processing a substrate includes loading the substrate into a processing chamber. A reaction gas is introduced into the processing chamber through a showerhead disposed in an upper region of the processing chamber. The showerhead includes a plurality of injection holes. The reaction gas is diffused using a baffle. The baffle includes a base plate disposed in a central portion of the showerhead. An extension plate is movably connected to a planar surface of the base plate in radial directions of the base plate to change a diameter of the baffle. The reaction gas is injected to the substrate through the injection holes of the showerhead to process the substrate.

A method of processing a substrate includes loading the substrate into a processing chamber. A reaction gas is introduced into a showerhead disposed in an upper region of the processing chamber. The showerhead includes a plurality of injection holes. The reaction gas is diffused using a baffle. The baffle is disposed in a central portion of the showerhead. The baffle has a diameter of about 0.05 times to about 0.15 times a length between outermost injection holes of the plurality of injection holes on a diameter line of the showerhead. The reaction gas is injected to the substrate through the injection holes of the showerhead to process the substrate.

### BRIEF DESCRIPTION OF THE DRAWINGS

Exemplary embodiments of the present disclosure will be more clearly understood from the following detailed description taken in conjunction with the accompanying drawings, wherein:

FIG. 1 is a cross-sectional view illustrating an apparatus for processing a substrate in accordance with exemplary embodiments of the present disclosure;

FIG. 2 is an enlarged cross-sectional view illustrating a showerhead and a baffle of the apparatus in FIG. 1;

FIG. 3 is a graph illustrating a flux difference between reaction gases supplied to a central portion and an edge portion of a substrate in accordance with a ratio of a baffle diameter with respect to a showerhead diameter;

FIG. 4 is a graph illustrating thicknesses of a layer on a substrate in accordance with a ratio of a baffle diameter with respect to a showerhead diameter;

FIG. 5 is an exploded perspective view illustrating a baffle in accordance with exemplary embodiments of the present disclosure;

FIG. 6 is a perspective view illustrating a base plate of the baffle in FIG. 5;

FIG. 7 is a perspective view illustrating the baffle having a minimum diameter by an extension plate in FIG. 5;

FIG. 8 is a plan view illustrating the baffle having a minimum diameter by an extension plate in FIG. 5;

FIG. 9 is a perspective view illustrating the baffle having a maximum diameter by an extension plate in FIG. 5;

FIG. 10 is a plan view illustrating the baffle having a maximum diameter by an extension plate in FIG. 5;

FIG. 11 is an exploded perspective view illustrating a baffle in accordance with exemplary embodiments of the present disclosure;

FIG. 12 is a perspective view illustrating the baffle in FIG. 11;

FIG. 13 is a cross-sectional view taken along a line XIII-XIII′ in FIG. 12;

FIG. 14 is a cross-sectional view taken along a line XIV-XIV′ in FIG. 12;

FIG. 15 is a plan view illustrating the baffle having a minimum diameter by an extension plate in FIG. 11;

FIG. 16 is a plan view illustrating the baffle having a maximum diameter by an extension plate in FIG. 11; and

FIG. 17 is a flow chart illustrating a method of processing a substrate using the apparatus in FIG. 1.

### DETAILED DESCRIPTION OF THE EMBODIMENTS

Hereinafter, exemplary embodiments of the present disclosure will be explained in detail with reference to the accompanying drawings.

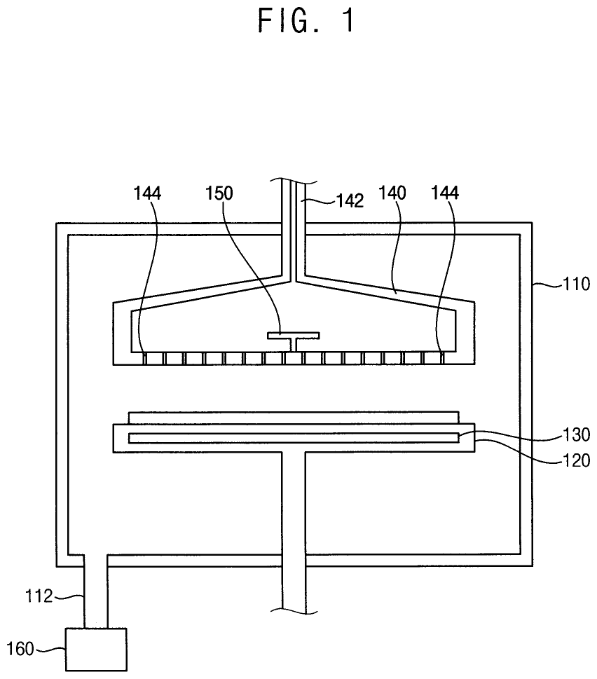

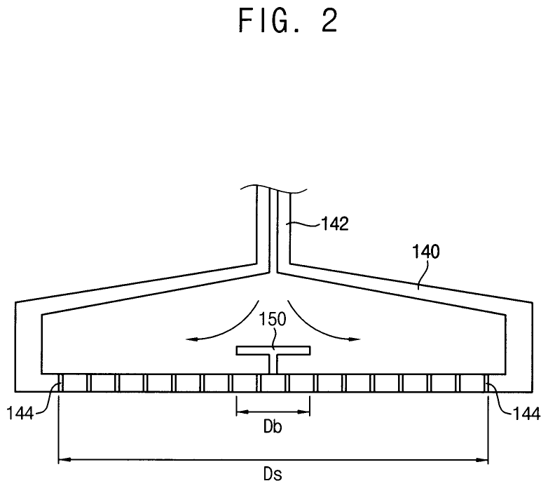

FIG. 1 is a cross-sectional view illustrating an apparatus for processing a substrate in accordance with exemplary embodiments of the present disclosure, and FIG. 2 is an enlarged cross-sectional view illustrating a showerhead and a baffle of the apparatus in FIG. 1.

Referring to FIGS. 1 and 2, an apparatus for processing a substrate in accordance with exemplary embodiments of the present disclosure may include an apparatus for forming a layer on the substrate. For example, the apparatus may include a chemical vapor deposition (CVD) apparatus.

The apparatus may include a processing chamber 110, a chuck 120, a heater 130, a showerhead 140, a baffle 150 and an exhaust pump 160. The chuck 120 may be disposed on a bottom surface of the processing chamber 110. The substrate may be placed on an upper surface of the chuck 120. The heater 130 may be built in the chuck 120. The processing chamber 110 may include an exhaust line 112 for exhausting processing byproducts. The exhaust line 112 may be connected to the bottom surface of the processing chamber 110. The exhaust pump 160 may be connected to the exhaust line 112.

The showerhead 140 may be disposed at an upper region in the processing chamber 110. The showerhead 140 may include an inlet 142 through which a reaction gas may be introduced into the processing chamber 110. The inlet 142 may be disposed at an upper central portion of the showerhead 140. The showerhead 140 may include a plurality of injection holes 144 for injecting the reaction gas, which may be introduced into the processing chamber through the inlet 142, to the substrate on the chuck 120. The injection holes 144 may be spaced apart from each other by a uniform gap.

Because the inlet 142 may be disposed at the upper central portion of the showerhead 140, an amount of the reaction gas supplied to the injection holes 144 at the central portion of the showerhead 140 may be greater than an amount of the reaction gas supplied to the injection holes 144 at an edge portion of the showerhead 140. In this case, the layer formed on a central portion of the substrate may be of a thickness that is greater than that of the layer on an edge portion of the substrate.

To provide the layer with a uniform thickness, the baffle 150 may be disposed in a central portion of the showerhead 140. The baffle 150 may diffuse the reaction gas, which may be introduced through the inlet 142, toward the edge portion of the showerhead 140 to reduce an amount deviation of the reaction gas supplied to the injection holes 144 (e.g. to help ensure that each of the injection holes 144 has a substantially identical flux of reaction gas). The baffle 150 may have a substantially circular, plate shape, however, other shapes may also be used.

As shown in FIG. 2, an amount of the reaction gas diffused toward the edge portion of the showerhead 140 may be proportional to a diameter Db of the baffle 150. For example, a distribution of the reaction gas in the showerhead 140 may be determined in accordance with the diameter Db of the baffle 150. Further, the distribution of the reaction gas may also be determined in accordance with a relation between a diameter of the showerhead 140 and the diameter Db of the baffle 150. Here, the diameter of the showerhead 140 may be a length Ds measured between outermost injection holes 144 disposed on a diameter line of the showerhead 140 among the entire injection holes 144. Thus, a ratio R of the diameter Db of the baffle 150 with respect to the length Ds between the outermost injection holes 144 of the showerhead 140 may determine the distribution of the reaction gas.

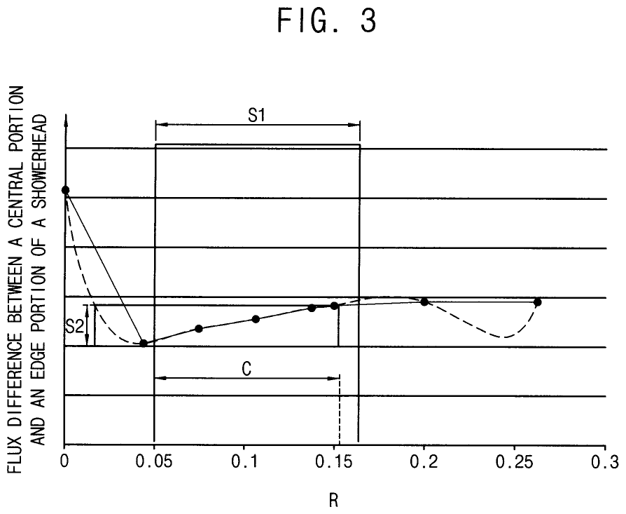

FIG. 3 is a graph showing a flux difference between reaction gases supplied to a central portion and an edge portion of a substrate in accordance with a ratio of a baffle diameter with respect to a showerhead diameter. In FIG. 3, a horizontal axis may represent the ratio R of the diameter Db of the baffle 150 with respect to the length Ds between the outermost injection holes 144 of the showerhead 140, and a vertical axis may represent a flux difference of the reaction gas between the central portion of the substrate and the edge portion of the substrate.

As shown in FIG. 3, when the ratio R may be gradually increased under a condition that a pressure of about 1 Torr to about 10 Torr may be applied to the processing chamber 110, it can be noted that the flux difference of the reaction gas may be linearly increased in a section S1. Further, it can be noted that a low flux deviation of the reaction gas in a section S2 may exist. Thus, it can be noted that a section C corresponding to a commonly intersected portion between the section S1 and the section S2 may ensure a uniform distribution of the reaction gas. A range of the ratio R in the common section C may be about 0.05 to about 0.15. For example, when the diameter Db of the baffle 150 may be about 0.05 times to about 0.15 times the length Ds between the outermost injection holes 144 of the showerhead 140, the reaction gas may be uniformly supplied to the injection holes 144 of the showerhead 140.

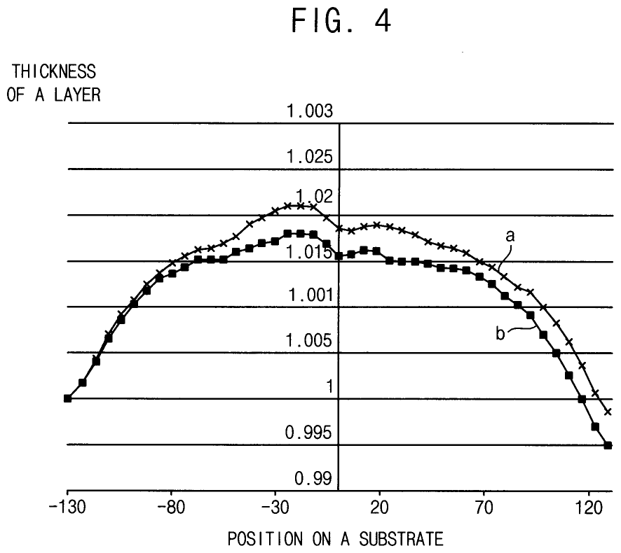

FIG. 4 is a graph showing thicknesses of a layer on a substrate in accordance with a ratio of a baffle diameter with respect to a showerhead diameter. In FIG. 4, a line a may indicate a thickness of the layer when the ratio R may be about 0.17, and a line b may indicate a thickness of the layer when the ratio R may be about 0.13.

As shown in FIG. 4, it can be noted that the thickness of the layer formed on the central portion of the substrate under the condition that the ratio R may be about 0.13 may be thinner than the thickness of the layer formed on the central portion of the substrate under the condition that the ratio R may be about 0.17. Therefore, when the diameter Db of the baffle 150 may be about 0.05 times to about 0.15 times the length Ds between the outermost injection holes 144 of the showerhead 140, it can be noted that the layer on the substrate may have a more uniform thickness.

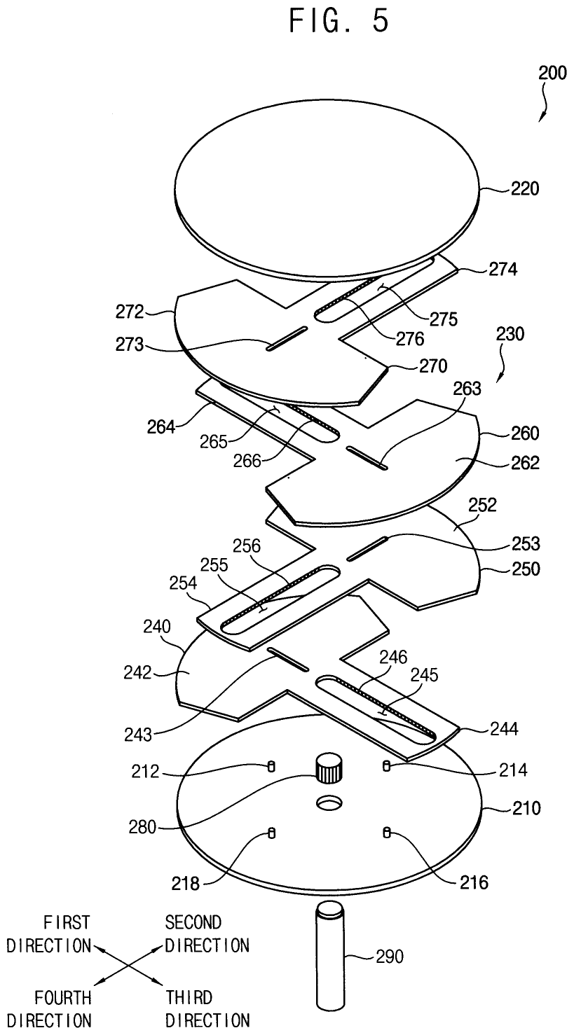

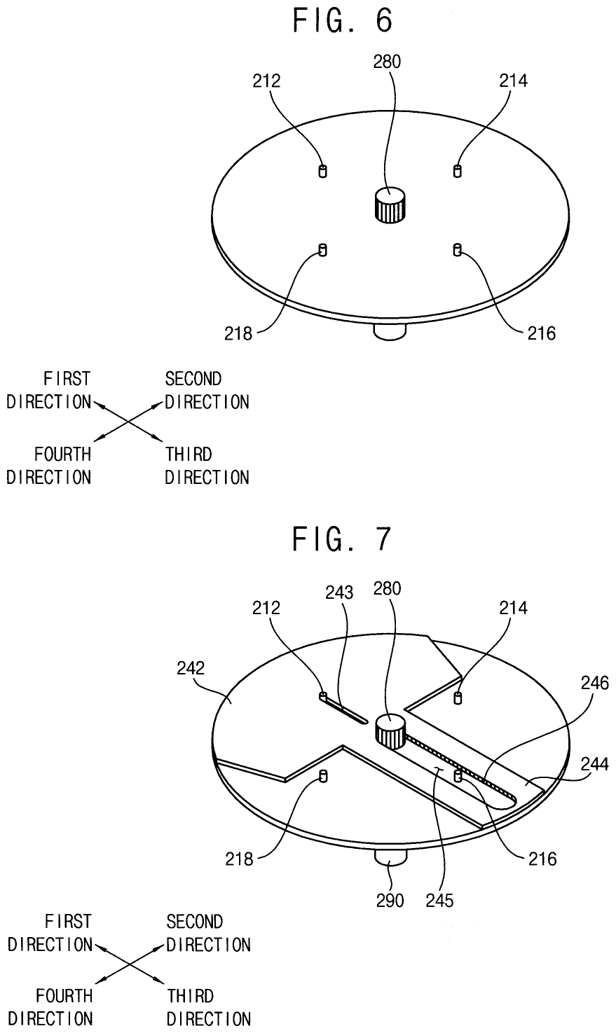

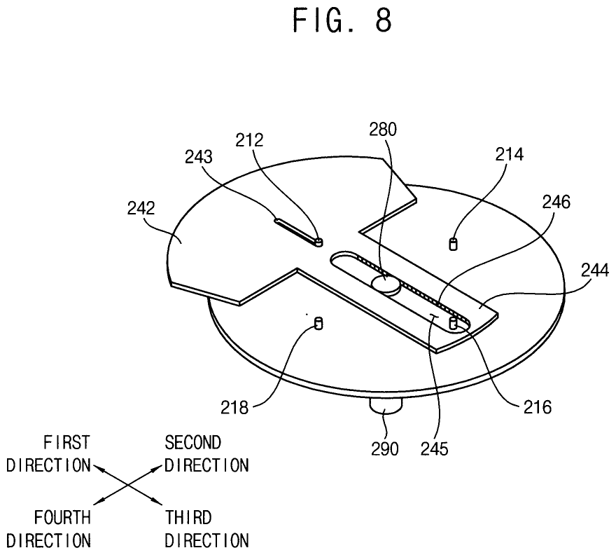

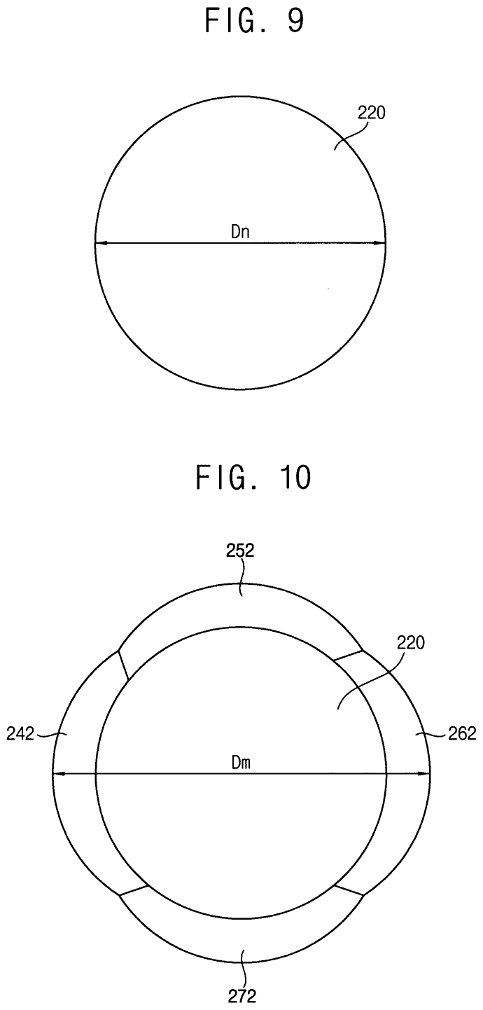

FIG. 5 is an exploded perspective view illustrating a baffle in accordance with exemplary embodiments of the present disclosure. FIG. 6 is a perspective view illustrating a base plate of the baffle in FIG. 5. FIGS. 7 and 8 are a perspective view and a plan view respectively illustrating the baffle having a minimum diameter by an extension plate in FIG. 5. FIGS. 9 and 10 are a perspective view and a plan view respectively illustrating the baffle having a maximum diameter by an extension plate in FIG. 5.

When it may be required to provide the diameter Db of the baffle 150 with about 0.05 times to about 0.15 times the length Ds between the outermost injection holes 144 of the showerhead 140 in accordance with a processing condition, the baffle 150 having the fixed diameter in FIG. 1 may be substituted with a baffle having the required diameter.

However, in order to prevent the substitution of the baffle, referring to FIGS. 5 and 6, a baffle 200 may have a variable diameter. For example, the baffle 200 may be arranged so as to dilate and contract to a desired diameter. The baffle 200 may include a base plate 210, a cover plate 220, and an extension plate 230.

The base plate 210 may be disposed in the central portion of the showerhead 140. The base plate 210 may have a circular plate shape, however, other shapes may be used. The base plate 210 may have a diameter of about 0.05 times the length Ds between the outermost injection holes 144 of the showerhead 140. For example, the diameter of the base plate 210 may be a minimum diameter of the baffle 200.

The base plate 210 may include a first guide protrusion 212, a second guide protrusion 214, a third guide protrusion 216, and a fourth guide protrusion 218. The first to fourth guide protrusions 212, 214, 216, and 218 may be disposed on an upper surface of the base plate 210. The first guide protrusion 212 may be disposed on a first radial direction of the plate 210. The second guide protrusion 214 may be disposed on a second radial direction of the plate 210 substantially perpendicular to the first radial direction. The third guide protrusion 216 may be disposed on a third radial direction of the base plate 210 substantially opposite to the first radial direction. The fourth guide protrusion 218 may be disposed on a fourth radial direction substantially opposite to the second radial direction. Thus, the first to fourth guide protrusions 212, 214, 216, and 218 may be spaced apart from each other by about 90°.

A gear 280 may be rotatably disposed on a central portion of the upper surface of the base plate 210. An actuator 290 may provide the gear 280 with a rotary force. Thus, the gear 280 may be rotated in a clockwise direction and a counterclockwise direction by the actuator 290. According to exemplary embodiments of the present disclosure, the actuator 290 may include a motor.

The cover plate 220 may be combined with the upper surface of the base plate 210. A space may be defined between the cover plate 220 and the base plate 210. The cover plate 220 may have a shape substantially the same as that of the base plate 210. Thus, the cover plate 220 may have a circular plate shape having a diameter substantially the same as that of the base plate 210.

The extension plate 230 may be disposed between the base plate 210 and the cover plate 220. The extension plate 230 may be moved on the base plate 210 in the first to fourth radial directions to selectively extend the diameter of the baffle 200.

The extension plate 230 may include a first plate 240, a second plate 250, a third plate 260, and a fourth plate 270. The first to fourth plates 240, 250, 260, and 270 may be sequentially stacked. The first to fourth plates 240, 250, 260, and 270 may have substantially the same shape.

The first plate 240 may be movably connected to the upper surface of the base plate 210 in the first radial direction. The first plate 240 may include a first extendable portion 242 and a first movable portion 244.

The first extendable portion 242 may be moved in the first radial direction to extend the diameter of the baffle 200 in the first radial direction. The first extendable portion 242 may have an outer circumferential surface having a curvature substantially the same as that of an outer circumferential surface of the base plate 210. Thus, the outer circumferential surface of the first extendable portion 242, which might not be moved in the first radial direction, may be substantially coplanar with the outer circumferential surface of the base plate 210. The first extendable portion 242 may have a first guide groove 243 formed in the first radial direction. The first guide protrusion 212 may be inserted into the first guide groove 243. The movement of the first extendable portion 242 in the first radial direction may be guided by the first guide groove 243 and the first guide protrusion 212.

The first movable portion 244 may be extended from an inner surface of the first extendable portion 242 toward the central portion of the base plate 210. The first movable portion 244 may have an elongated rectangular plate shape. A first movement groove 245 may be formed through the first movable portion 244 in the first radial direction. A first rack 246 may be formed on inner surfaces of the first movement groove 245. The gear 280 may be engaged with the first rack 246. Thus, the first movable portion 244 may be moved forward and backward along the first radial direction in accordance with the rotation directions of the gear 280.

The second plate 250 may be movably connected to an upper surface of the first plate 240 in the second radial direction. The second plate 250 may include a second extendable portion 252 and a second movable portion 254.

The second extendable portion 252 may be moved in the second radial direction to extend the diameter of the baffle 200 in the second radial direction. The second extendable portion 252 may have an outer circumferential surface having a curvature substantially the same as that of an outer circumferential surface of the base plate 210. Thus, the outer circumferential surface of the second extendable portion 252, which might not be moved in the second radial direction, may be substantially coplanar with the outer circumferential surface of the base plate 210. The second extendable portion 252 may have a second guide groove 253 formed in the second radial direction. The second guide protrusion 214 may be inserted into the second guide groove 253. The movement of the second extendable portion 252 in the second radial direction may be guided by the second guide groove 253 and the second guide protrusion 214.

The second movable portion 254 may be extended from an inner surface of the second extendable portion 252 toward the central portion of the base plate 210. The second movable portion 254 may have an elongated rectangular plate shape. A second movement groove 255 may be formed through the second movable portion 254 in the second radial direction. A second rack 256 may be formed on inner surfaces of the second movement groove 255. The gear 280 may be engaged with the second rack 256. Thus, the second movable portion 254 may be moved forward and backward along the second radial direction in accordance with the rotation directions of the gear 280.

The third plate 260 may be movably connected to an upper surface of the second plate 250 in the third radial direction. The third plate 260 may include a third extendable portion 262 and a third movable portion 264.

The third extendable portion 262 may be moved in the third radial direction to extend the diameter of the baffle 200 in the third radial direction. The third extendable portion 262 may have an outer circumferential surface having a curvature substantially the same as that of an outer circumferential surface of the base plate 210. Thus, the outer circumferential surface of the third extendable portion 262, which might not be moved in the third radial direction, may be substantially coplanar with the outer circumferential surface of the base plate 210. The third extendable portion 262 may have a third guide groove 263 formed in the third radial direction. The third guide protrusion 216 may be inserted into the third guide groove 263. The movement of the third extendable portion 262 in the third radial direction may be guided by the third guide groove 263 and the third guide protrusion 216.

The third movable portion 264 may be extended from an inner surface of the third extendable portion 262 toward the central portion of the base plate 210. The third movable portion 264 may have an elongated rectangular plate shape. A third movement groove 265 may be formed through the third movable portion 264 in the third radial direction. A third rack 266 may be formed on inner surfaces of the third movement groove 265. The gear 280 may be engaged with the third rack 266. Thus, the third movable portion 264 may be moved forward and backward along the third radial direction in accordance with the rotation directions of the gear 280.

The fourth plate 270 may be movably connected to an upper surface of the third plate 260 in the fourth radial direction. The fourth plate 270 may include a fourth extendable portion 272 and a fourth movable portion 274.

The fourth extendable portion 272 may be moved in the fourth radial direction to extend the diameter of the baffle 200 in the fourth radial direction. The fourth extendable portion 272 may have an outer circumferential surface having a curvature substantially the same as that of an outer circumferential surface of the base plate 210. Thus, the outer circumferential surface of the fourth extendable portion 272, which might not be moved in the third radial direction, may be substantially coplanar with the outer circumferential surface of the base plate 210. The fourth extendable portion 272 may have a fourth guide groove 273 formed in the fourth radial direction. The fourth guide protrusion 218 may be inserted into the fourth guide groove 273. The movement of the fourth extendable portion 272 in the fourth radial direction may be guided by the fourth guide groove 273 and the fourth guide protrusion 218.

The fourth movable portion 274 may be extended from an inner surface of the fourth extendable portion 272 toward the central portion of the base plate 210. The fourth movable portion 274 may have an elongated rectangular plate shape. A fourth movement groove 275 may be formed through the fourth movable portion 274 in the fourth radial direction. A fourth rack 276 may be formed on inner surfaces of the fourth movement groove 275. The gear 280 may be engaged with the fourth rack 276. Thus, the fourth movable portion 274 may be moved forward and backward along the fourth radial direction in accordance with the rotation directions of the gear 280.

Therefore, as shown in FIGS. 7 and 8, when the first to fourth plates 240, 250, 260, and 270 are not protruded from the base plate 210, the baffle 200 may have a diameter corresponding to the diameter of the base plate 210. For example, the baffle 200 may have a minimum diameter Dn of about 0.05 times the length Ds between the outermost injection holes 144 of the showerhead 140.

In contrast, as shown in FIGS. 9 and 10, when the first to fourth plates 240, 250, 260, and 270 may be protruded from the base plate 210 in the first to fourth radial directions, respectively, the baffle 200 may have an extended diameter corresponding to a length of each of protruded portions of the first to fourth extendable portions 242, 252, 262, and 272 from the base plate 210. For example, the baffle 200 may have a maximum diameter Dm of about 0.15 times the length Ds between the outermost injection holes 144 of the showerhead 140 when the protruded portion are maximally extended. However, it is to be understood that any desired diameter from the minimum diameter to the maximum diameter may be achieved by extending each protruded portion to a desired degree. Moreover, while the shape of the baffle in maximum extension may be seen in FIG. 10, it is to be understood that other structures may be used to create a baffle that can dilate and contract.

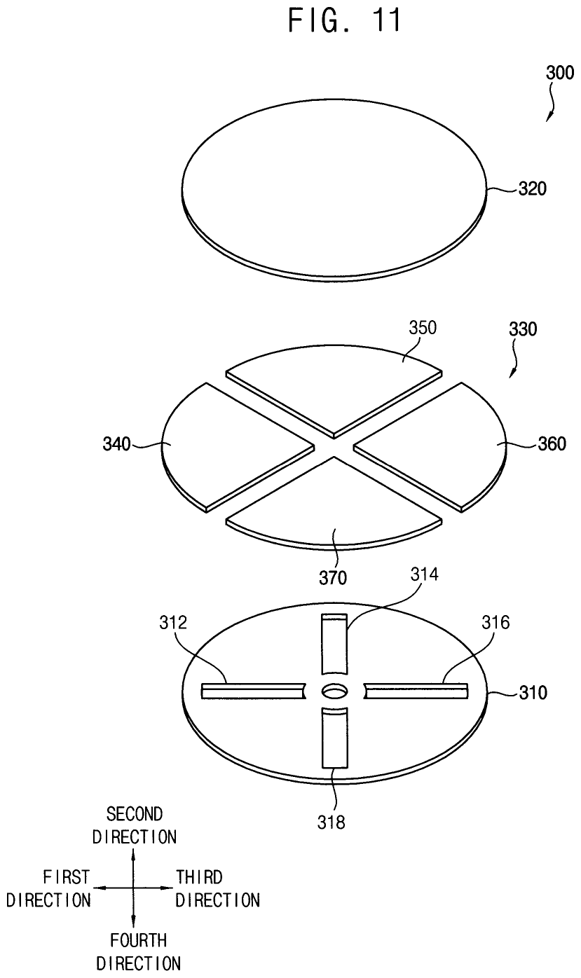

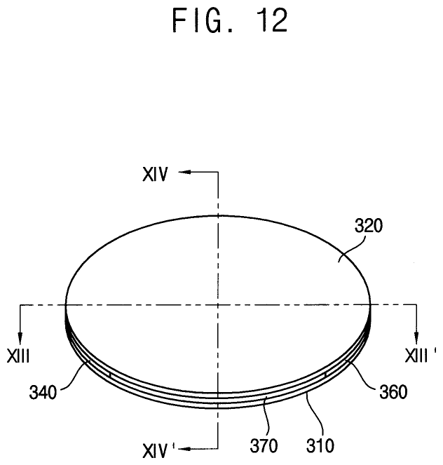

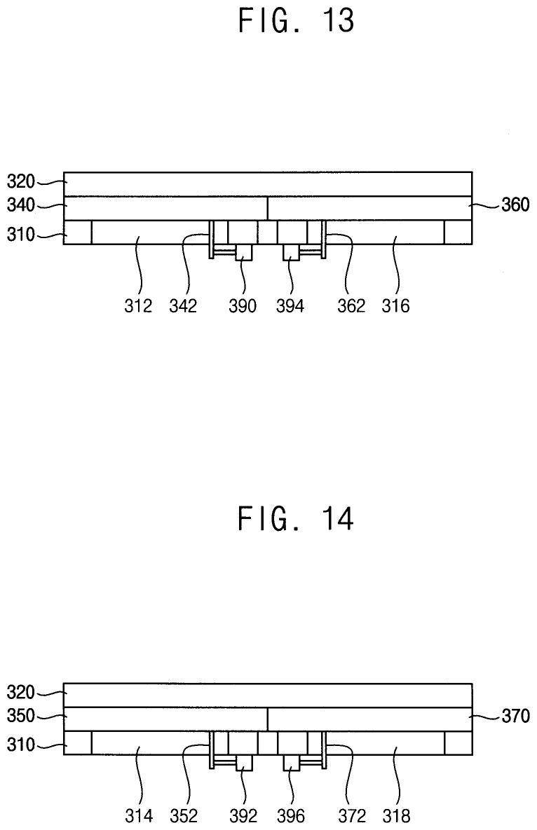

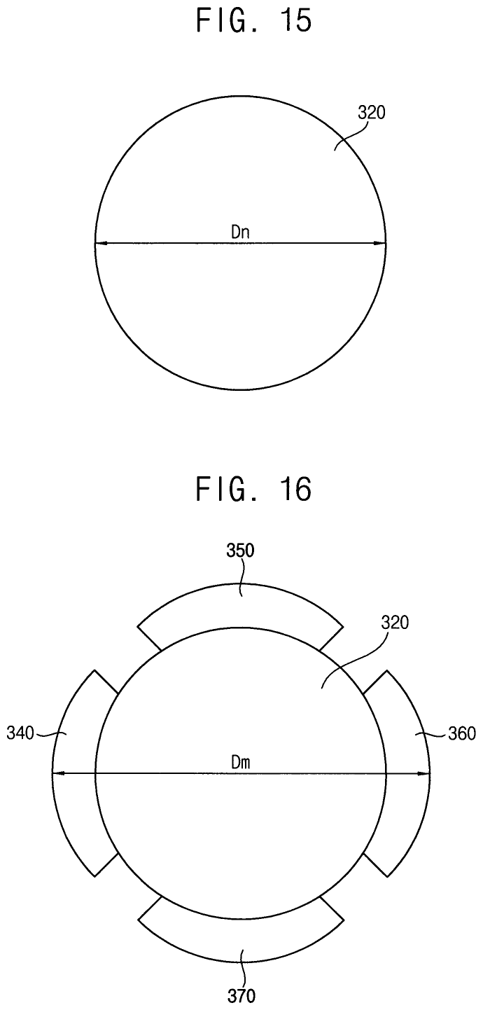

FIG. 11 is an exploded perspective view illustrating a baffle in accordance with exemplary embodiments of the present disclosure. FIG. 12 is a perspective view illustrating the baffle in FIG. 11. FIG. 13 is a cross-sectional view taken along a line XIII-XIII′ in FIG. 12. FIG. 14 is a cross-sectional view taken along a line XIV-XIV′ in FIG. 12. FIG. 15 is a plan view illustrating the baffle having a minimum diameter by an extension plate in FIG. 11. FIG. 16 is a plan view illustrating the baffle having a maximum diameter by an extension plate in FIG. 11.

Referring to FIGS. 11 to 14, a baffle 300 may include a base plate 310, a cover plate 320 and an extension plate 330.

The base plate 310 may be disposed in the central portion of the showerhead 140. The base plate 310 may have a circular plate shape, however other shapes may be used. The base plate 310 may have a diameter of about 0.05 times the length Ds between the outermost injection holes 144 of the showerhead 140.

The base plate 310 may include a first guide groove 312, a second guide groove 314, a third guide groove 316 and a fourth guide groove 318. The first guide groove 312 may be formed at the base plate 310 in the first radial direction. The second guide groove 314 may be formed at the base plate 310 in the second radial direction. The third guide groove 316 may be formed at the base plate 310 in the third radial direction. The fourth guide groove 318 may be formed at the base plate 310 in the fourth radial direction.

The cover plate 320 may be combined with an upper surface of the base plate 310. A space may be formed between the cover plate 320 and the base plate 310. The cover plate 320 may have a shape substantially the same as that of the base plate 310.

The extension plate 330 may be disposed between the base plate 310 and the cover plate 320. The extension plate 330 may include a first plate 340, a second plate 350, a third plate 360, and a fourth plate 370. The first to fourth plates 340, 350, 360, and 370 may have a quarter of a circular arc shape. The first to fourth plates 340, 350, 360, and 370 may be formed by cutting a circular plate, which may have a size and a shape substantially the same as those of the base plate 310, in the first to fourth radial directions.

The first plate 340 may be movably disposed on the upper surface of the base plate 310 in the first radial direction. The first plate 340 may include a first movable protrusion 342. The first movable protrusion 342 may be disposed on a lower surface of the first plate 340. The first movable protrusion 342 may be inserted into the first guide groove 312. The first movable protrusion 342 may be exposed through the lower surface of the base plate 310 and the first guide groove 312.

A first actuator 390 may be installed at the lower surface of the base plate 310. The first actuator 390 may be connected to a lower end of the first movable protrusion 342 exposed from the lower surface of the base plate 310. The first actuator 390 may move the first movable protrusion 342 forward and backward in the first radial direction. According to exemplary embodiments of the present disclosure, the first actuator 390 may include a cylinder.

The second plate 350 may be movably disposed on the upper surface of the base plate 310 in the second radial direction. The second plate 350 may include a second movable protrusion 352. The second movable protrusion 352 may be disposed on a lower surface of the second plate 350. The second movable protrusion 352 may be inserted into the second guide groove 314. The second movable protrusion 352 may be exposed through the lower surface of the base plate 310 and the second guide groove 314.

A second actuator 392 may be installed at the lower surface of the base plate 310. The second actuator 392 may be connected to a lower end of the second movable protrusion 352 exposed from the lower surface of the base plate 310. The second actuator 392 may move the second movable protrusion 352 forward and backward in the second radial direction. According to exemplary embodiments of the present disclosure, the second actuator 392 may include a cylinder.

The third plate 360 may be movably disposed on the upper surface of the base plate 310 in the third radial direction. The third plate 360 may include a third movable protrusion 362. The third movable protrusion 362 may be disposed on a lower surface of the third plate 360. The third movable protrusion 362 may be inserted into the third guide groove 316. The third movable protrusion 362 may be exposed through the lower surface of the base plate 310 and the third guide groove 316.

A third actuator 394 may be installed at the lower surface of the base plate 310. The third actuator 394 may be connected to a lower end of the third movable protrusion 362 exposed from the lower surface of the base plate 310. The third actuator 394 may move the third movable protrusion 362 forward and backward in the third radial direction. According to exemplary embodiments of the present disclosure, the third actuator 394 may include a cylinder.

The fourth plate 370 may be movably disposed on the upper surface of the base plate 310 in the fourth radial direction. The fourth plate 370 may include a fourth movable protrusion 372. The fourth movable protrusion 372 may be disposed on a lower surface of the fourth plate 370. The fourth movable protrusion 372 may be inserted into the fourth guide groove 318. The fourth movable protrusion 372 may be exposed through the lower surface of the base plate 310 and the fourth guide groove 318.

A fourth actuator 396 may be installed at the lower surface of the base plate 310. The fourth actuator 396 may be connected to a lower end of the fourth movable protrusion 372 exposed from the lower surface of the base plate 310. The fourth actuator 396 may move the fourth movable protrusion 372 forward and backward in the fourth radial direction. According to exemplary embodiments of the present disclosure, the fourth actuator 396 may include a cylinder.

Therefore, as shown in FIG. 15, when the first to fourth plates 340, 350, 360, and 370 are not protruded from the base plate 310, the baffle 300 may have a diameter corresponding to the diameter of the base plate 310. For example, the baffle 300 may have a minimum diameter Dn of about 0.05 times the length Ds between the outermost injection holes 144 of the showerhead 140.

In contrast, as shown in FIG. 16, when the first to fourth plates 340, 350, 360, and 370 may be protruded from the base plate 310 in the first to fourth radial directions, respectively, the baffle 300 may have an extended diameter corresponding to a length of each of protruded portions of the first to fourth plates 340, 350, 360, and 370 from the base plate 310. For example, the baffle 300 may have a maximum diameter Dm of about 0.15 times the length Ds between the outermost injection holes 144 of the showerhead 140.

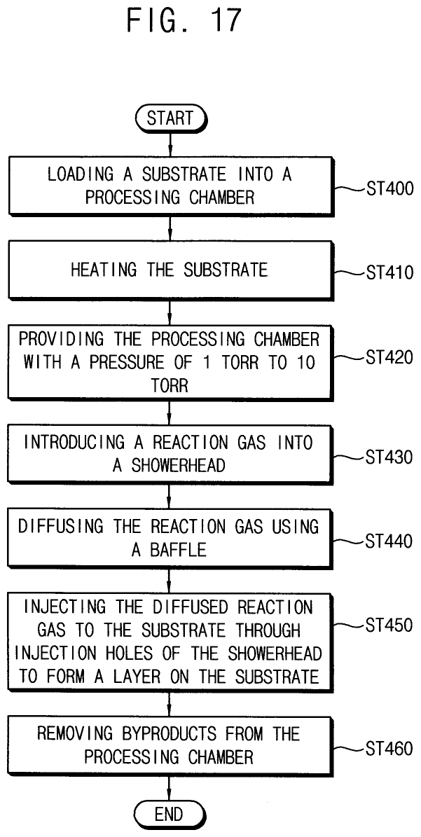

FIG. 17 is a flow chart illustrating a method of processing a substrate using the apparatus in FIG. 1.

Referring to FIGS. 1 and 17, in step ST400, the substrate may be loaded into the processing chamber 110. The substrate may then be placed on the upper surface of the chuck 120.

In step ST410, the heater 130 in the chuck 120 may heat the substrate.

In step ST420, the processing chamber 110 may be pressurized to a pressure of about 1 Torr to about 10 Torr.

In step ST430, the reaction gas may be introduced into the showerhead 140 through the inlet 142.

In step ST440, the baffle 150 may horizontally diffuse the reaction gas introduced into the central portion of the showerhead 140. According to exemplary embodiments of the present disclosure, because the diameter of the baffle 150 may be about 0.05 times to about 0.15 times the length Ds between the outermost injection holes 144 of the showerhead 140, the reaction gas may be uniformly supplied to the injection holes 144 of the showerhead 140.

Alternatively, the reaction gas may be diffused using the baffle 200 in FIG. 5 or the baffle 300 in FIG. 11.

In step ST450, the uniformly diffused reaction gas may be injected to the substrate on the chuck 120 through the injection holes 144 of the showerhead 140. Thus, a layer having a uniform thickness may be formed on the substrate.

In step ST460, the exhaust pump 160 may exhaust byproducts generated in the processing chamber 110 to remove the byproducts from the processing chamber 110.

According to exemplary embodiments of the present disclosure, the diameter of the baffle may be about 0.05 times to about 0.15 times the length between the outermost injection holes on the diameter line of the showerhead to uniformly diffuse the reaction gas into the showerhead. Thus, the reaction gas may be uniformly provided to the substrate through the injection holes of the showerhead so that a layer formed on the substrate may have a uniform thickness. For example, the baffle may have the ability to vary its diameter by the degree to which the extension plate is extended so that the diameter of about 0.05 times to about 0.15 times the length between the outermost injection holes may be provided to the baffle in accordance with processing conditions.

The foregoing is illustrative of exemplary embodiments of the present disclosure and the invention should not be seen as limited to the exemplary embodiments shown. Those skilled in the art will readily appreciate that many modifications are possible in the described exemplary embodiments without materially departing from the present invention.

What is claimed is:

1. A baffle, comprising:
a base plate disposed in a central portion of a showerhead in an apparatus for processing a substrate; and
an extension plate movably connected to a planar surface of the base plate,
wherein the extension plate is configured to extend and contract radially from the base plate to change a diameter of the baffle.

2. The baffle of claim 1, wherein the extension plate comprises:
a first plate movably connected to the planar surface of the base plate in a first radial direction of the base plate;
a second plate movably connected to the planar surface of the base plate in a second radial direction substantially perpendicular to the first radial direction;
a third plate movably connected to the planar surface of the base plate in a third radial direction substantially opposite to the first radial direction; and
a fourth plate movably connected to the planar surface of the base plate in a fourth radial direction substantially opposite to the second radial direction.

3. The baffle of claim 2, wherein the first to fourth plates are sequentially stacked.

4. The baffle of claim 2, wherein the first to fourth plates have substantially the same shape as one another.

5. The baffle of claim 4, wherein each of the first to fourth plates comprises:
an extendable portion movably disposed on the planar surface of the base plate in the first to fourth radial directions to extend a diameter of the base plate, the extendable portion including a guide groove extended in each of the first to fourth radial directions; and
a movable portion extended from the extendable portion toward a central portion of the base plate.

6. The baffle of claim 5, wherein the base plate comprises a guide protrusion disposed on the first to fourth radial directions and inserted into the guide groove.

7. The baffle of claim 5, wherein the movable portion comprises a movement groove formed in the first radial direction, and a rack is formed on an inner surface of the movement groove, and the rack is engaged with a gear disposed at the central portion of the base plate.

8. The baffle of claim 7, further comprising an actuator configured to rotate the gear.

9. The baffle of claim 5, wherein the base plate has a substantially circular shape, and the extendable portion has a curvature substantially the same as a curvature of the substantially circular base plate.

10. The baffle of claim 4, wherein each of the first to fourth plates has a sector shape equal to one quarter of a circle.

11. The baffle of claim 10, wherein the base plate has a substantially circular shape, and the extendable portion has a curvature substantially the same as a curvature of the substantially circular base plate.

12. The baffle of claim 11, wherein the base plate comprises first to fourth guide grooves extended in the first to fourth radial directions, respectively.

13. The baffle of claim 12, wherein the first to fourth plates comprise first to fourth movable protrusion movably inserted into the first to fourth guide grooves, respectively.

14. The baffle of claim 13, further comprising first to fourth actuators configured to move the first to fourth movable protrusions in the first to fourth guide grooves, respectively.

15. The baffle of claim 1, further comprising a cover plate disposed over the extension plate and combined with the base plate.

16. The baffle of claim 15, wherein the base plate and the cover plate have substantially the same circular shape.

17. A showerhead assembly, comprising:
a showerhead including a plurality of injection holes; and
a baffle including a base plate, the baffle being disposed in a central portion of the showerhead, the baffle further including an extension plate movably connected to a planar surface of the base plate so as to extend in radial directions to change a diameter of the baffle.

18. The showerhead assembly of claim 17, wherein the base plate has a diameter of about 0.05 times a length between outermost injection holes of the plurality of injection holes on a diameter line of the showerhead.

19. The showerhead assembly of claim 18, wherein the baffle has a maximum diameter attained by a maximum extension of the extension plate, and the maximum diameter is about 0.15 times the length between the outermost injection holes.

20. The showerhead assembly of claim 17, wherein the extension plate comprises:
a first plate movably connected to the planar surface of the base plate in a first radial direction of the base plate;
a second plate movably connected to the planar surface of the base plate in a second radial direction substantially perpendicular to the first radial direction;
a third plate movably connected to the planar surface of the base plate in a third radial direction substantially opposite to the first radial direction; and
a fourth plate movably connected to the planar surface of the base plate in a fourth radial direction substantially opposite to the second radial direction.

21. The showerhead assembly of claim 20, wherein the first to fourth plates are sequentially stacked.

22. The showerhead assembly of claim 20, wherein the first to fourth plates have substantially the same shape as each other.

23. The showerhead assembly of claim 17, further comprising a cover plate disposed over the extension plate and combined with the base plate.

24. The showerhead assembly of claim 23, wherein the base plate and the cover plate have substantially the same circular shape.

25. A showerhead assembly, comprising:
a showerhead including a plurality of injection holes; and
a baffle disposed in a central portion of the showerhead, the baffle having a diameter of about 0.05 times to about 0.15 times a length between outermost injection holes of the plurality of injection holes on a diameter line of the showerhead.

26. The showerhead assembly of claim 25, wherein the baffle comprises:
a base plate disposed in the central portion of a showerhead, the base plate having a diameter of about 0.05 times the length between the outermost injection holes; and
an extension plate movably connected to a planar surface of the base plate in radial directions of the base plate to provide the baffle with the diameter of about 0.15 times the length between the outermost injection holes.

27. The showerhead assembly of claim 26, wherein the extension plate comprises:
a first plate movably connected to the planar surface of the base plate in a first radial direction of the base plate;
a second plate movably connected to the planar surface of the base plate in a second radial direction substantially perpendicular to the first radial direction;
a third plate movably connected to the planar surface of the base plate in a third radial direction substantially opposite to the first radial direction; and
a fourth plate movably connected to the planar surface of the base plate in a fourth radial direction substantially opposite to the second radial direction.

28. The showerhead assembly of claim 26, further comprising a cover plate disposed over the extension plate and combined with the base plate.

29. The showerhead assembly of claim 28, wherein the base plate and the cover plate have substantially the same circular shape.

30. An apparatus for processing a substrate, the apparatus comprising:
a processing chamber;
a chuck disposed on a bottom surface of the processing chamber and supporting the substrate;
a showerhead disposed in an upper region of the processing chamber, the showerhead including a plurality of injection holes configured to inject a reaction gas to the substrate; and
a baffle including a base plate, the baffle disposed in a central portion of the showerhead, the baffle further including an extension plate movably connected to a planar surface of the base plate in radial directions of the base plate to change a diameter of the baffle.

31. The apparatus of claim 30, wherein the base plate has a diameter of about 0.05 times a length between outermost injection holes of the plurality of injection holes on a diameter line of the showerhead.

32. The apparatus of claim 31, wherein the baffle has a maximum diameter extended by the extension plate, and the maximum diameter is about 0.15 times the length between the outermost injection holes.

33. The apparatus of claim 30, further comprising a heater in the chuck.

34. The apparatus of claim 30, wherein the processing chamber comprises a deposition chamber configured to deposit a layer on the substrate.

35. The apparatus of claim 34, wherein the deposition chamber comprises a chemical vapor deposition (CVD) chamber.

36. An apparatus for processing a substrate, the apparatus comprising:
a processing chamber;
a chuck disposed on a bottom surface of the processing chamber and configured to support the substrate;
a showerhead disposed in an upper region of the processing chamber, the showerhead including a plurality of injection holes each of which configured for injecting a reaction gas to the substrate; and
a baffle disposed in a central portion of the showerhead, the baffle having a diameter of about 0.05 times to about 0.15 times a length between outermost injection holes of the plurality of injection holes on a diameter line of the showerhead.

37. The apparatus of claim 36, wherein the baffle comprises:
a base plate disposed in the central portion of a showerhead, the base plate having a diameter of about 0.05 times the length between the outermost injection holes; and
an extension plate movably connected to a planar surface of the base plate in radial directions of the base plate to provide the baffle with the diameter of about 0.15 times the length between the outermost injection holes.

38. The apparatus of claim 36, further comprising a heater within the chuck.

39. The apparatus of claim 36, wherein the processing chamber comprises a deposition chamber for depositing a layer on the substrate.

40. The apparatus of claim 39, wherein the deposition chamber comprises a chemical vapor deposition (CVD) chamber.

41. A method of processing a substrate, the method comprising:
loading the substrate into a processing chamber;
introducing a reaction gas into the processing chamber through a showerhead disposed in an upper region of the processing chamber, the showerhead including a plurality of injection holes;
diffusing the reaction gas using a baffle, the baffle including a base plate disposed in a central portion of the showerhead, and an extension plate movably connected to a planar surface of the base plate in radial directions of the base plate to change a diameter of the baffle; and
injecting the reaction gas to the substrate through the injection holes of the showerhead to process the substrate.

42. The method of claim 41, further comprising pressurizing the processing chamber to a pressure of about 1 Torr to about 10 Torr.

43. The method of claim 41, further comprising heating the substrate.

44. The method of claim 41, wherein processing the substrate comprises forming a layer on the substrate.

45. A method of processing a substrate, the method comprising:
loading the substrate into a processing chamber;
introducing a reaction gas into a showerhead disposed in an upper region of the processing chamber, the showerhead including a plurality of injection holes;
diffusing the reaction gas using a baffle, the baffle disposed in a central portion of the showerhead, the baffle having a diameter of about 0.05 times to about 0.15 times a length between outermost injection holes of the plurality of injection holes on a diameter line of the showerhead; and
injecting the reaction gas to the substrate through the injection holes of the showerhead to process the substrate.

46. The method of claim 45, further comprising pressurizing the processing chamber to a pressure of about 1 Torr to about 10 Torr.

47. The method of claim 45, further comprising heating the substrate.

48. The method of claim 45, wherein processing the substrate comprises forming a layer on the substrate.
